(19) United States
(12) Patent Application Publication
(10) Pub. No.: US 2023/0209868 A1
(43) Pub. Date: Jun. 29, 2023

(54) Electroluminescence Display

(71) Applicant: LG Display Co., Ltd., Seoul (KR)

(72) Inventor: TaeHan Park, Paju-si (KR)

(21) Appl. No.: 17/975,319

(22) Filed: Oct. 27, 2022

(30) Foreign Application Priority Data
Dec. 29, 2021 (KR) 10-2021-0191329

(51) Int. Cl. H01L 51/52; H01L 27/32

(52) U.S. Cl. CPC H01L 51/5253; H01L 27/3244; H01L 2251/303

(57) ABSTRACT

An electroluminescence display is disclosed. The electroluminescence display includes a cathode electrode having an encapsulation function. The electroluminescence display comprises: a substrate; an anode electrode on the substrate; an emission layer on the anode electrode; and a cathode electrode on the emission layer. The cathode electrode includes a plurality of conductive layers that are sequentially stacked.

### CROSS-REFERENCE TO RELATED APPLICATION

This application claims the benefit of the Republic of Korea Patent Application No. 10-2021-0191329 filed on Dec. 29, 2021, which is hereby incorporated by reference in its entirety.

### BACKGROUND

### Field of Technology

The present disclosure relates to an electroluminescence display including a cathode electrode having an encapsulation function. In particular, the present disclosure relates to an electroluminescence display in which a cathode electrode layer functions as an encapsulation layer without an additional encapsulation layer for protecting the light emitting element.

### Discussion of the Related Art

Recently, various type of display such as the cathode ray tubes (CRTs), the liquid crystal displays (LCDs), the plasma display panels (PDPs) and the electroluminescent displays have been developed. These various types of display are used to display image data of various products such as computer, mobile phones, bank deposit and withdrawal devices (ATMs), and vehicle navigation systems according to their unique characteristics and purposes.

In particular, in the case of an electroluminescence display which is a self-luminous display, when foreign materials such as moisture and gas penetrate into an organic element from outside the display, the organic element may be damaged and the service life is shortened. In order to prevent this problem, a technique for applying an encapsulation layer to protect the organic light emitting element has been proposed.

To provide the encapsulation layer, a separate process is required, thereby increasing the manufacturing tack time and cost. In addition, when the encapsulation layer has defective interface characteristics with the cathode electrode of the organic light emitting diode, the encapsulation performance may not be fully ensured. Therefore, it is necessary to develop a technology for an encapsulation layer having a new structure capable of preventing the penetration of moisture or foreign materials from the outside, while simplifying the manufacturing process and reducing the manufacturing costs.

### SUMMARY

The purpose of the present disclosure, as for solving the problems described above, is to provide an electroluminescence display having excellent encapsulation performance by a cathode electrode itself without a separate encapsulation layer for protecting the organic light emitting element. Another purpose of the present disclosure is to provide an electroluminescence display capable of reducing manufacturing cost by simplifying a manufacturing process by configuring a cathode electrode to have an encapsulation function.

In one embodiment, an electroluminescence display comprises: a substrate; an anode electrode on the substrate; an emission layer on the anode electrode; and a cathode electrode on the emission layer. The cathode electrode includes a plurality of conductive layers that are sequentially stacked.

In one embodiment, an electroluminescence display device comprises: a substrate; a transistor on the substrate; a passivation layer on the transistor; a planarization layer on the passivation layer, the planarization layer having a side surface; a light emitting element on the planarization layer and electrically connected to the transistor, the light emitting element including an anode electrode, an emission layer on the anode electrode, and a multi-layer cathode electrode on the emission layer, wherein the multi-layer cathode electrode extends past the emission layer such that at least a portion of the multi-layer cathode electrode overlaps the side surface of the planarization layer and is on the passivation layer.

The electroluminescent display according to the present disclosure may have a structure in which at least two conductive layers of a cathode electrode configuring an organic light emitting element are sequentially stacked. For example, it has a structure in which a first conductive layer including a metal material such as aluminum and a second conductive layer including a metal oxide layer such as aluminum oxide are stacked. Accordingly, the cathode electrode further includes an encapsulation function, so that the cathode electrode and the encapsulation layer may be formed into one structure in a single process of forming the cathode electrode. As a result, the manufacturing process is simplified and manufacturing cost may be reduced. In addition, since the cathode electrode having an encapsulation function is formed with a structure made of a multilayer conductive material, the adhesion force between the thin film is excellent, and damage such as a peeling phenomenon does not occur. Therefore, the present disclosure may provide an electroluminescence display including a cathode electrode having an excellent encapsulation function that blocks foreign materials from penetrating from the outside.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of an electroluminescence display according to the present disclosure.

FIG. 2 is a circuit diagram illustrating a structure of one pixel included in the electroluminescence display according to the present disclosure.

FIG. 3 is a plan view illustrating a structure of the pixels disposed in the electroluminescence display according to the present disclosure.

FIG. 4 is a cross-sectional view along to cutting line II-II′ in FIG. 3 illustrating a structure of the electroluminescence display according to the present disclosure.

FIG. 5 is a cross-sectional view along to cutting line I-I′ in FIG. 3 illustrating a structure of the electroluminescence display according to the present disclosure.

FIG. 6 is a cross-sectional view along to cutting line III-III′ in FIG. 1 illustrating a structure of the electroluminescence display according to the present disclosure.

FIGS. 7A and 7B are cross-sectional views, enlarging the rectangular area X in FIG. 4, for illustrating a stack structure of a light emitting diode of the electroluminescence display according to a first embodiment of the present disclosure.

FIG. 8 is a cross-sectional view, enlarging the rectangular area X in FIG. 4, for illustrating a stack structure of a light emitting diode of the electroluminescence display according to a second embodiment of the present disclosure.

FIG. 9 is a cross-sectional view, enlarging the rectangular area X in FIG. 4, for illustrating a stack structure of a light emitting diode of the electroluminescence display according to a third embodiment of the present disclosure.

FIG. 10 is a cross-sectional view, enlarging the rectangular area X in FIG. 4, for illustrating a stack structure of a light emitting diode of the electroluminescence display according to a fourth embodiment of the present disclosure.

FIG. 11 is a cross-sectional view, enlarging the rectangular area X in FIG. 4, for illustrating a stack structure of a light emitting diode of the electroluminescence display according to a fifth embodiment of the present disclosure.

FIG. 12 is a cross-sectional view, enlarging the rectangular area X in FIG. 4, for illustrating a stack structure of a light emitting diode of the electroluminescence display according to a sixth embodiment of the present disclosure.

FIG. 13 is a cross-sectional view for illustrating a stack structure of a light emitting diode of the electroluminescence display according to a seventh embodiment of the present disclosure.

FIG. 14 is a cross-sectional view for illustrating a stack structure of a light emitting diode of the electroluminescence display according to an eighth embodiment of the present disclosure.

FIG. 15 is a cross-sectional view for illustrating a stack structure of a light emitting diode of the electroluminescence display according to a nineth embodiment of the present disclosure.

FIG. 16 is a cross-sectional view for illustrating a stack structure of a light emitting diode of the electroluminescence display according to another example of the nineth embodiment of the present disclosure.

FIG. 17 is a cross-sectional view for illustrating a stack structure of a light emitting diode of the electroluminescence display according to a first application example of the present disclosure.

FIG. 18 is a cross-sectional view for illustrating a stack structure of a light emitting diode of the electroluminescence display according to a second application example of the present disclosure.

FIG. 19 is a cross-sectional view for illustrating a stack structure of a light emitting diode of the electroluminescence display according to a third application example of the present disclosure.

FIG. 20 is a cross-sectional view for illustrating a stack structure of a light emitting diode of the electroluminescence display according to a fourth application example of the present disclosure.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts. Since a scale of each of elements shown in the accompanying drawings may be different from an actual scale for convenience of description, the present disclosure is not limited to the scale shown in the drawings.

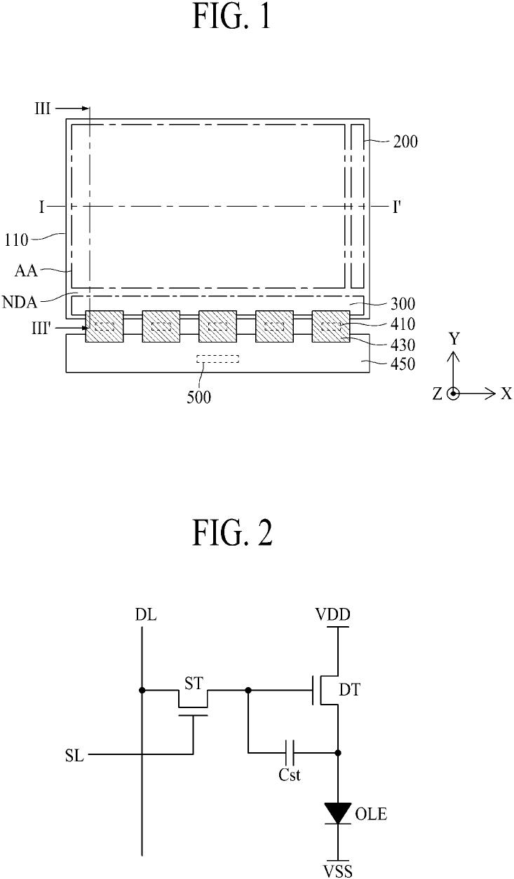

Hereinafter, referring to the attached figures, the present disclosure will be explained. FIG. 1 is a plane view illustrating a schematic structure of an electroluminescence display according to the present disclosure. In FIG. 1, X-axis refers to the direction parallel to the scan line (e.g., a first direction), Y-axis refers to the direction of the data line (e.g., a second direction), and Z-axis refers to the height direction (e.g., a third direction) of the display device.

Referring to FIG. 1, the electroluminescence display comprises a substrate 110, a gate (or scan) driver 200, a data pad portion 300, a source driving IC (integrated circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the electroluminescence display is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be defined at the periphery areas of the substrate 110 surrounding all or some of the display area AA. In the non-display area NDA, the gate driver 200 and the data pad portion 300 may be formed or disposed.

The gate driver 200 may supply the scan (or gate) signals to the scan lines according to the gate control signal received from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110.

The data pad portion 300 may supply the data signals to the data line according to the data control signal received from the timing controller 500. The data pad portion 300 may be made as a driver chip and mounted on the flexible film 430. Further, the flexible film 430 may be attached at the non-display area NDA at any one outside of the display area AA on the substrate 110, as a TAB (tape automated bonding) type.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the data pad portion 300 to the source driving IC 410, and a plurality of second link lines connecting the data pad portion 300 to the circuit board 450. The flexible film 430 may be attached on the data pad portion 300 using an anisotropic conducting film, so that the data pad portion 300 may be connected to the first link lines of the flexible film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

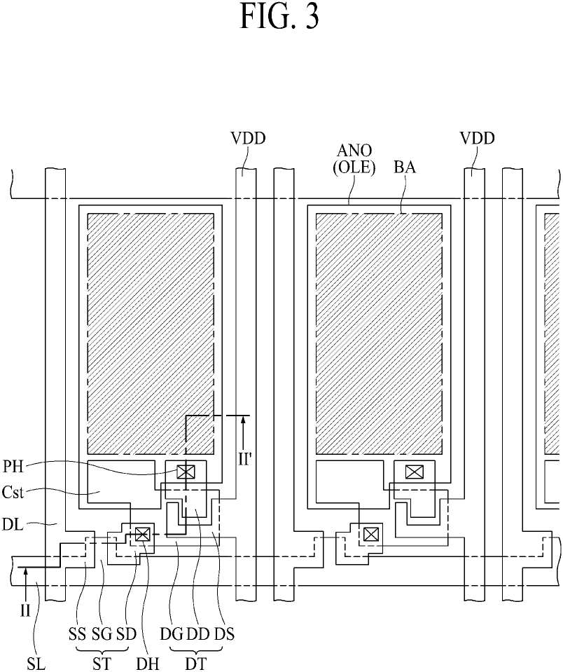

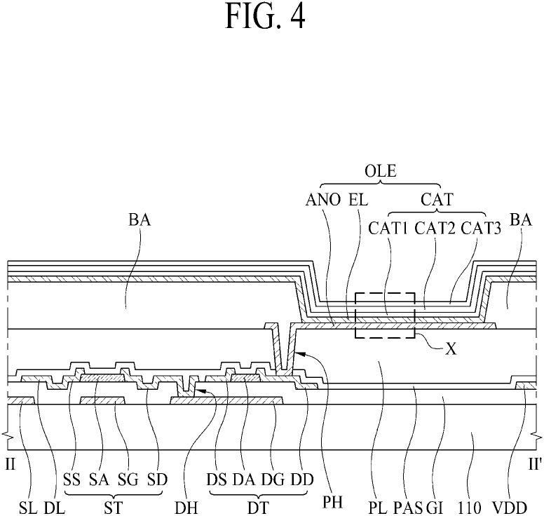

Hereinafter, referring to FIGS. 2 to 4, one embodiment of the present disclosure will be explained. FIG. 2 is a circuit diagram illustrating a structure of one pixel according to the present disclosure. FIG. 3 is a plan view illustrating a structure of the pixels according to the present disclosure. FIG. 4 is a cross-sectional view along cutting line II-II′ in FIG. 3 illustrating a structure of the electroluminescent display according to the present disclosure.

Referring to FIGS. 2 to 4, one pixel of the light emitting display may be defined by a scan line SL, a data line DL and a driving current line VDD. One pixel of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

A switching thin film transistor ST and a driving thin film transistor DT may be formed on a substrate SUB. For example, the switching thin film transistor ST may be disposed at the portion where the scan line SL and the data line DL cross each other. The switching thin film transistor ST may include a switching gate electrode SG, a switching semiconductor layer SA, a switching source electrode SS and a switching drain electrode SD. The switching gate electrode SG may be connected to the scan line SL. The switching semiconductor layer SA may overlap with the switching gate electrode SG. The switching source electrode SS may be connected to the data line DL and the switching drain electrode SD may be connected to the driving thin film transistor DT. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a driving gate electrode DG, a driving semiconductor layer DA, a driving source electrode DS and a driving drain electrode DD. The driving gate electrode DG may be connected to the switching drain electrode SD of the switching thin film transistor ST. For example, the driving gate electrode DG may be connected to the switching drain electrode SD via the drain contact hole DH penetrating the gate insulating layer GI. The driving semiconductor layer DA may overlap with the driving gate electrode DG. The driving source electrode DS may be connected to the driving current line VDD, and the driving drain electrode DD may be connected to an anode electrode ANO of the light emitting diode OLE. A storage capacitance Cst may be disposed between the driving gate electrode DG of the driving thin film transistor DT and the anode electrode ANO of the light emitting diode OLE.

The driving thin film transistor DT may be disposed between the driving current line VDD and the light emitting diode OLE. The driving thin film transistor DT may control the amount of electric currents flowing to the light emitting diode OLE from the driving current line VDD according to the voltage level of the driving gate electrode DG connected to the switching drain electrode SD of the switching thin film transistor ST.

The light emitting diode OLE may include an anode electrode ANO, a light emitting layer EL and a cathode electrode CAT. The light emitting diode OLE may emit the light according to the amount of the electric current controlled by the driving thin film transistor DT. In other word, the light emitting diode OLE may be driven by the voltage differences between the low-level voltage and the high-level voltage controlled by the driving thin film transistor DT. The anode electrode ANO of the light emitting diode OLE may be connected to the driving drain electrode DD of the driving thin film transistor DT, and the cathode electrode CAT may be connected to a low-level voltage line Vss where a low-level potential voltage is supplied. That is, the light emitting diode OLE may be driven by the high-level voltage controlled by the driving thin film transistor DT and the low-level voltage supplied from the low-level voltage line Vss.

On the substrate 110 having the thin film transistors ST and DT, a passivation layer PAS may be deposited. The passivation layer PAS may be made of an inorganic material such as silicon oxide (SiOx) or silicon nitride (SiNx). A planarization layer PL may be deposited on the passivation layer PAS. The planarization layer PL may be a thin film for flattening or evening the non-uniform surface of the substrate 110 on which the thin film transistors ST and DT are formed. To do so, the planarization layer PL may be made of the organic materials. The passivation layer PAS and the planarization layer PL may have a pixel contact hole PH for exposing some portions of the drain electrode DD of the driving thin film transistor DT.

On the surface of the planarization layer PL, an anode electrode ANO may be formed. The anode electrode ANO may be connected to the drain electrode DD of the driving thin film transistor DT via the pixel contact hole. The anode electrode ANO may have different elements according to the emission condition of the light emitting diode OLE. For the bottom emission type in which the emitted light may be provided to the substrate 110, i the anode electrode ANO may be made of a transparent conductive material in one embodiment. For the top emission type in which the emitted light may be provided to the direction opposite the substrate 110, in one embodiment the anode electrode ANO may include a metal material with excellent reflection ratio.

In the case of the present disclosure, since the cathode electrode has an encapsulation function thereby obviating the need for an encapsulation structure that is on the cathode electrode, it has a structure suitable for a bottom emission type. In the case of the bottom emission type, the anode electrode ANO may be formed of a transparent conductive material. For example, the anode electrode ANO may include an oxide conductive material such as indium-zinc-oxide (IZO) or indium-tin-oxide (ITO). The anode electrode ANO may be configured with a single layer or multiple layers. The anode electrode ANO may include a low reflective material. For example, when the anode electrode ANO is formed of a low reflection electrode, the anode electrode ANO may include a lower layer including molybdenum-copper oxide (MoCuOx) and an upper layer including copper (Cu).

On the anode electrode ANO, a bank BA may be formed. The bank BA may define an emission area by covering the circumference area of the anode electrode ANO and exposing most middle areas of the anode electrode ANO. An emission layer EL may be deposited on the anode electrode ANO and the bank BA. The emission layer EL may be deposited over the whole surface of the display area AA on the substrate 110, as covering the anode electrodes ANO and banks BA. For an example, the emission layer EL may include two or more stacked emission portions for emitting white light. In detail, the emission layer EL may include a first emission layer providing first color light and a second emission layer providing second color light, for emitting the white light by combining the first color light and the second color light.

In another example, the emission layer EL may include at least any one of blue-light emission layer, green-light emission layer and red-light emission layer as corresponding to the color allocated to the pixel. In addition, the light emitting diode OLE may further include at least one functional layer for enhancing the light emitting efficiency and/or the service lifetime of the emission layer EL.

The cathode electrode CAT may be disposed on the emission layer EL. The cathode electrode CAT may be stacked on the emission layer EL as being surface contact each other. The cathode electrode CAT may be formed as one sheet element over the whole area of the substrate 110 as being commonly connected whole emission layers EL disposed at all pixels. In the case of the bottom emission type, the cathode electrode CAT may include metal material having excellent light reflection ratio. For example, the cathode electrode CAT may include at least any one of silver (Ag), aluminum (Al), molybdenum (Mo), gold (Au), magnesium (Mg), calcium (Ca), or barium (Ba).

The display according to the present disclosure does not include a separated encapsulation layer on the light emitting diode OLE because the cathode electrode CAT works as an encapsulation layer. In order to configure the cathode electrode CAT to have an encapsulation function, it has a unique structural feature of the present disclosure.

For the display according to the present disclosure, the cathode electrode CAT includes at least two cathode electrode layers. In one embodiment, the cathode electrode CAT may include a plurality of cathode electrode layers (e.g., three cathode electrode layers) sequentially stacked. Thus, the cathode electrode CAT is a multi-layered cathode electrode. For example, the cathode electrode CAT may include at least two of a first cathode layer CAT1, a second cathode layer CAT2 and a third cathode layer CAT3 which are sequentially stacked. In one embodiment, the cathode electrode CAT may include a first cathode layer CAT1, a second cathode layer CAT2, and a third cathode layer CAT3.

The first cathode layer CAT1 may be firstly stacked on the emission layer EL so as to be in direct surface contact with the emission layer EL. The first cathode layer CAT1 may include an inorganic material such as a metal material having relatively low surface resistance. For example, the first cathode layer CAT1 may include any one of aluminum (Al), silver (Ag), molybdenum (Mo), gold (Au), magnesium (Mg), calcium (Ca) and barium (Ba). Considering the manufacturing process and cost, a case in which the first cathode layer CAT1 may be formed of aluminum will be explained as one example. In the case that the first cathode layer CAT1 is made of a metal material such as aluminum, the first cathode layer CAT1 may be formed a thickness of 100 Å to 3,000 Å. When the thickness of first cathode layer CAT1 is thinner than 100 Å, it may be difficult to maintain a stable common electrode condition because the sheet resistance of the cathode electrode CAT may be increased. When the thickness of the first cathode layer CAT1 is thicker than 3,000 Å, the manufacturing tack time may increase and the manufacturing cost may increase.

The second cathode layer CAT2 may include conductive resin materials. The conductive resin materials may include a domain material made of a resin material with high electron mobility and a dopant for lowering the barrier energy of the domain material. The resin materials having high electron mobility may include any one selected from Alq3, TmPyPB, Bphen, TAZ and TPB. Alq3 may be an abbreviation of ‘Tris(8-hydroxyquinoline) Aluminum’, and be a complex having a chemical formula of Al(C₉H₆NO)₃. TmPyPB may be an organic material that is an abbreviation of ‘1,3,5-tri(m-pyrid-3-yl-phenyl) benzene’. Bphen may be an organic material that is an abbreviation of ‘Bathophenanthroline’. TAZ may be organic material that is an abbreviation for 1,2,3-triazole. TPB may be organic material that is an abbreviation for triphenyl bismuth. Since these organic materials have high electron mobility, they may be used in a light emitting element.

The dopant materials may include an alkali-based doping material. For example, the dopant materials may include at least any one of lithium (Li), cesium (Cs), cesium oxide (Cs₂O₃), cesium nitride (CsN₃), rubidium (Rb) and rubidium oxide (Rb₂O). In another example, the dopant materials may include fullerene having high electron mobility. Fullerene may be a generic term for molecules in which carbon atoms are arranged in a sphere, ellipsoid or cylinder shape. For example, the dopant materials may include Buckminster-fullerene (C60) in which 60 carbon atoms are mainly bonded in the shape of a soccer ball. In addition, the dopant materials may include higher fullerenes such as C70, C76, C78, C82, C90, C94 and C96.

The second cathode layer CAT2 may have the same materials as the electron transporting layer or electron injecting layer included into the emission layer EL. However, unlike the electron transporting layer or the electron injecting layer, the second cathode layer CAT2 may have higher electron mobility than the electron transporting layer or the electron injecting layer. For example, the electron transporting layer or the electron injecting layer may have the electron mobility of 5.0×10⁻⁴(S/m) to 9.0×10⁻¹(S/m), whereas the second cathode layer CAT2 may have an electron mobility of 1.0×10⁻³(S/m) to 9.0×10⁺¹(S/m). For this, the conductive resin materials included into the second cathode layer CAT2 may have a dopant content higher than that of the electron transporting layer or the electron injecting layer.

For example, the electron transporting layer or the electron injecting layer has a dopant doping concentration of 0% to 5%, whereas the second cathode layer CAT2 may be a conductive resin material having a dopant doping concentration of 3% to 30% according to one embodiment. In one embodiment, the doping concentration of the second cathode layer CAT2 is equal to or greater than that of the electron transparent layer or the electron injection layer. The dopant material itself, in which the dopant has a doping concentration of 0%, may have an electrical conductivity of 1.0×10⁻⁴₍S/m) to 5.0×10⁻³(S/m). By doping 3% to 30% of dopant into the dopant material, the second cathode layer CAT2 may have improved electrical conductivity to 1.0×10⁻ ³(S/m) to 9.0×10⁺¹(S/m) to be used as a cathode electrode.

In one case, the second cathode layer CAT2 may have the same conductivity as the electron functional layer (electron transporting layer and/or electron injecting layer) of the emission layer EL. In this case, the sheet resistance of the cathode electrode CAT may be maintained at a sufficiently low value due to the first cathode layer CAT1 made of aluminum.

The third cathode layer CAT3 may be include an inorganic material. In particular, when the third cathode layer CAT3 is stacked at the last layer, the third cathode layer CAT3 may include an oxide metal material. For example, the third cathode layer CAT3 may include any one of aluminum oxide (Al₂O₃), barium oxide (BaO), magnesium oxide (MgO), molybdenum oxide (MoO), or calcium oxide (CaO). When the first cathode layer CAT1 is made of aluminum, as considering the manufacturing process, the third cathode layer CAT3 is preferably made of aluminum oxide.

The metal oxide material may prevent or at least reduce penetration of oxygen from the outside the display device. Accordingly, the third cathode layer CAT3 is formed to completely cover the second cathode layer CAT2 and the first cathode layer CAT1 formed thereunder.

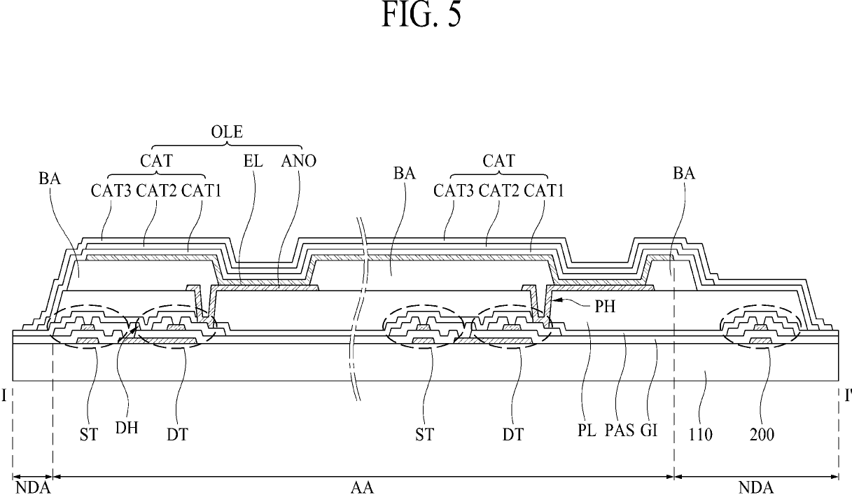

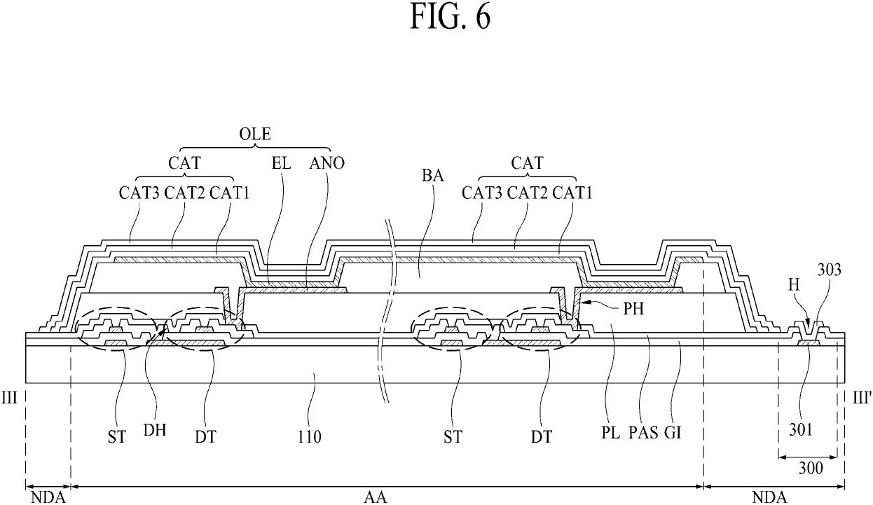

Referring to FIGS. 5 and 6, the detailed stack structure of the cathode electrode CAT deposited over the entire surface of the substrate 110 will be explained. FIG. 5 is a cross-sectional view along to cutting line I-I′ in FIG. 3 illustrating a structure of the electroluminescence display according to the present disclosure. FIG. 6 is a cross-sectional view along to cutting line III-III′ in FIG. 1 illustrating a structure of the electroluminescence display according to the present disclosure.

FIG. 5 is a cross-sectional view cutting across the gate driver 200. Referring to FIG. 5, an electroluminescence display according to the present disclosure comprises thin film transistors ST and DT on a substrate 110. A passivation layer PAS is deposited on the thin film transistors ST and DT. The passivation layer PAS may be stacked as covering entire surface of the substrate 110. A planarization layer PL is deposited on the passivation layer PAS. The planarization layer PL may be formed of an organic material in order to planarize the surface of the substrate 110 having a roughened surface as the thin film transistors ST and DT are formed. Since the organic material is vulnerable to moisture or oxygen, the organic material is formed in the display area AA but not in the non-display area NDA. Otherwise, as shown in FIG. 5, the planarization layer PL may extend from the display area AA to the gate driver 200. In any case, the planarization layer PL is stacked so as not to cover the entire surface of the substrate 110.

A light emitting diode OLE is formed on the planarization layer PL. The emission layer EL of the light emitting diode OLE may have an area size corresponding to the display area AA. In some cases, the emission layer EL may have a larger size than that of the display area AA. Meanwhile, the cathode electrode CAT is stacked on the emission layer EL to completely cover the emission layer EL with a larger area than the emission layer EL. The cathode electrode CAT may include the first cathode layer CAT1, the second cathode layer CAT2 and the third cathode layer CAT3 sequentially stacked.

The first cathode layer CAT1 may be deposited as fully covering the emission layer EL. For example, the first cathode layer CAT1 may have larger area than the emission layer EL to fully cover the edges of the emission layer EL. In addition, the first cathode layer CAT1 may be formed to fully cover the planarization layer PL. For example, the emission layer EL covers the display area AA, but has the smaller area than the planarization layer PL. The first cathode layer CAT1 may be stacked as having a cross-sectional profile in which it fully covers (overlaps) the vertical side surface at the edges (e.g., vertical sides) of the planarization layer PL, and the first cathode layer CAT1 is in surface contact (e.g., direct contact) with the upper surface of the passivation layer PAS exposed to the outside of the planarization layer PL.

The second cathode layer CAT2, in particular, when the second cathode layer CAT is formed of a conductive resin material, as shown in FIG. 5, may be stacked in an area smaller than that of the planarization layer PL to cover the emission layer EL on the first cathode layer CAT1 completely. However, the second cathode layer CAT has an area that is smaller than an area of the first cathode layer CAT1 and thus does not cover edges of the first cathode layer CAT1 as shown in FIG. 5. In another example, the second cathode layer CAT2 may have a larger area than the first cathode layer CAT1 and may be formed to completely cover the edges of the first cathode layer CAT1.

The third cathode layer CAT3 may be deposited as fully covering the first cathode layer CAT1 and the second cathode layer CAT2. For example, the third cathode layer CAT3 may have a larger area than the first cathode layer CAT1 and the second cathode layer CAT2 to cover edges of the first cathode layer CAT1 and the second cathode layer CAT2 completely. For example, when the second cathode layer CAT2 has smaller area than the first cathode layer CAT1, the third cathode layer CAT3 is formed to cover the first cathode layer CAT1 completely. In another example, when the second cathode layer CAT2 is formed to cover the first cathode layer CAT1, the third cathode layer CAT3 is formed to cover the second cathode layer CAT2 completely.

As shown in FIG. 5, the planarization layer PL may be deposited to cover the gate driver 200. In addition, the first cathode layer CAT1 and the third cathode layer CAT3 among the cathode electrode CAT may extend to cover the gate driver 200 completely. In some cases, the planarization layer PL may be deposited not to cover the gate driver 200. In this case, the gate driver 200 may be covered by the passivation layer PAS. The first cathode layer CAT1 and the third cathode layer CAT3 may cover the gate driver 200 or may not cover the gate driver 200. In the view of device protection, the first cathode layer CAT1 and the third cathode layer CAT3 may cover the gate driver 200 completely.

Next, it will be described with reference to FIG. 6. FIG. 6 is a cross-sectional view cutting across the data pad portion 300. Referring to FIG. 6, the electroluminescence display according to the present disclosure comprises thin film transistors ST and DT formed on the substrate 110. The passivation layer PAS is deposited on the thin film transistors ST and DT. The passivation layer PAS is deposited as covering the entire surface of the substrate 110. The planarization layer PL is deposited on the passivation layer PAS. The planarization layer PL may be formed of an organic material in order to planarize the surface of the substrate 110 having a roughened surface as the thin film transistors ST and DT are formed. Since the organic material is vulnerable to moisture or oxygen, the organic material is formed in the display area AA but not the non-display area NDA. On the other hand, the passivation layer PAS made of an inorganic material has excellent property for protecting the moisture and oxygen, it is preferable that the passivation layer PAS is deposited over entire surface of the substrate 110.

The light emitting diode OLE is formed on the planarization layer PL. In particular, the cathode electrode CAT has the first cathode layer CAT1, the second cathode layer CAT2 and the third cathode layer CAT3 sequentially stacked.

The data pad portion 300 includes a pad electrode 301. The pad electrode 301 may be covered by the gate insulating layer GI and the passivation layer PAS, but its middle portion may be exposed by the pad contact hole H. The pad electrode 301 may be disposed at the same layer with the gate electrode. A pad terminal 303 is formed on the pad electrode 301. The pad terminal 303 may be formed on the passivation layer PAS, and connected to the pad electrode 301 via the pad contact hole H. The pad terminal 303 may be made of the same material with the source-drain electrodes or the anode electrode.

The pad electrode 301 may include a data pad electrode, a driving current pad electrode and a low-voltage pad electrode. The data pad electrode may be disposed at the end of the data line DL. The driving current pad electrode may be disposed at the end of the driving current line VDD. The low-voltage pad electrode may be disposed at the end of the low-voltage line VSS.

The pad terminal 303 may include a data pad terminal corresponding to the data pad electrode, a driving current pad terminal corresponding to the driving current pad electrode, and a low-voltage pad terminal corresponding to the low-voltage pad electrode. The pad terminal 303 may be formed as having an island shape corresponding to the pad electrode 301. Even though not shown in figures, low-voltage pad electrode may be connected to the cathode electrode CAT to be supplied with the low-voltage power.

Referring to FIG. 6, the first cathode layer CAT1 is formed as covering the emission layer EL completely. For example, the emission layer EL may cover entire of the display area AA, and have a smaller area than the planarization layer PL. The first cathode layer CAT1 may cover the vertical surface at the edges of the planarization layer PL, and contact the upper surface of the passivation layer PAS exposed from the planarization layer PL.

The second cathode layer CAT2 may be formed as having larger area than the first cathode layer CAT1 and covering entire of the first cathode layer CAT1 including the edges of the first cathode layer CAT1 completely. In another example, the second cathode layer CAT2 may be formed as having smaller size of the first cathode layer CAT1. In FIG. 6, the second cathode layer CAT2 is stacked on the first cathode layer CAT1 with larger size than the first cathode layer CAT1.

The third cathode layer CAT3 may be deposited as completely covering the first cathode layer CAT1 and the second cathode layer CAT2. For example, the third cathode layer CAT3 may have larger area size than the first cathode layer CAT1 and the second cathode layer CAT2 for completely covering the edges of the first cathode layer CAT1 and the second cathode layer CAT2. In the case that the second cathode layer CAT2 covers the first cathode layer CAT1 completely, as shown in FIG. 6, it is preferable that the third cathode layer CAT3 completely covers the second cathode layer CAT2. In another example in which the second cathode layer CAT2 has smaller area size than the first cathode layer CAT1, the third cathode layer CAT3 covers the first cathode layer CAT1 completely.

The third cathode layer CAT3 may completely cover the edges of the first cathode layer CAT2 and the first cathode layer CAT1, and further extended therefrom. As the third cathode layer CAT3 covers all layers thereunder completely, it may works as the encapsulation layer for preventing the oxygen and foreign material from intruding from external environment.

In addition, the cathode electrode CAT may have a structure in which the passivation layer PAS is exposed from the cathode electrode CAT. As the passivation layer PAS is made of inorganic material, it may prevent or at least reduce oxygen and foreign material from intruding from the outer environment. Since the cathode electrode CAT may have a structure for sealing all layers made of organic material completely, the cathode electrode CAT may work as an encapsulation layer.

The metal oxide material may have a very low value of electron mobility compared to the metal material. For example, aluminum oxide is known as a non-conductive material. However, when a thin layer of the aluminum oxide is deposited with a thickness of 200 Å or less, it may be in a state in which it can easily overcome the work function barrier that prevents electron movement. Therefore, the thin aluminum oxide layer can have conductive characteristics, so it can be used as a common electrode. Meanwhile, when the thickness of the aluminum oxide material is thinner than 10 Å, the thin aluminum oxide layer may not be uniformly formed on the entire surface, but may be stacked in a separated island shape. Accordingly, the aluminum oxide layer is not deposited over the entire surface, so that it may not be possible to prevent oxygen or foreign materials from intruding from the out environment. Therefore, when the third cathode layer CAT3 is made of metal oxide material, it is preferable that the thickness of the third cathode layer CAT3 is any one of 10 Å to 200 Å.

Consequently, the cathode electrode CAT according to the present disclosure may have a structure in which at least three layers of a first cathode layer CAT1, a second cathode layer CAT2 and a third cathode layer CAT3 are sequentially stacked. All of the first cathode layer CAT1, the second cathode layer CAT2 and the third cathode layer CAT3 may be made of conductive thin layers. In one embodiment, the cathode electrode CAT may include a metal material such as aluminum having a relatively low sheet resistance. The metal oxide material included in the cathode electrode CAT may have a thickness of 10 Å to 200 Å in order to ensure the electron mobility. For this, the conductive resin material may include an alkali metal dopant in a doping concentration of 3% to 30% in the domain resin material having high electron mobility.

In some cases, the doping concentration of the conductive resin material may be at the same level as that of the electron function layer included in the emission layer of the light emitting diode. In these cases, the thickness of the first cathode layer CAT1 including a metal material is at least 500 Å to 3,000 Å, and set the overall sheet resistance of the cathode electrode CAT to match the conditions of the common low level electrode.

Until now, the most basic and structure in the electroluminescence display according to the present disclosure has been described as an example. Hereinafter, referring to figures, embodiments of various stacked structures of the cathode electrode CAT in the display according to the present disclosure will be described.

### First Embodiment

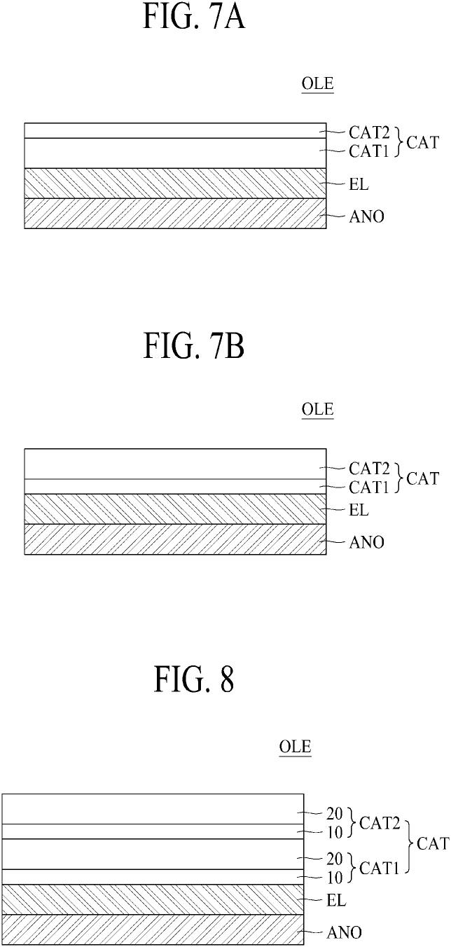

Referring to FIGS. 7A and 7B, a structure of an electroluminescence display according to the first embodiment of the present disclosure will be explained. In convenience, the description may be focused on the light emitting diode OLE. FIGS. 7A and 7B are cross-sectional views, enlarging the rectangular area X in FIG. 4, for illustrating a stack structure of a light emitting diode of the electroluminescence display according to a first embodiment of the present disclosure.

Referring to FIG. 7A, a light emitting diode according the first embodiment of the present disclosure includes an anode electrode ANO, an emission layer EL and a cathode electrode CAT. In particular, the cathode electrode CAT includes a first cathode layer CAT1 and a second cathode layer CAT2 sequentially stacked.

The first cathode layer CAT1 may include a metal material. For example, the first cathode layer CAT1 may include any one metal of aluminum (Al), silver (Ag), molybdenum (Mo), gold (Au), magnesium (Mg), calcium (Ca) and barium (Ba). The first cathode layer CAT1 may have a thickness of 100 Å to 3,000 Å.

The second cathode layer CAT2 may include a metal oxide material. For example, the second cathode layer CAT2 may include a metal oxide material selected at least one of aluminum oxide (Al₂O₃), molybdenum oxide (MoO), magnesium oxide (MgO), calcium oxide (CaO) and arium oxide (BaO). The second cathode layer CAT2 may have a thickness of 10 Å to 200 Å. Here, it is preferable that the first cathode layer CAT1 made of metal material is thicker than the second cathode layer CAT2 made of metal oxide material.

Referring to FIG. 7B, the light emitting diode according to the first embodiment of the present disclosure includes the anode electrode ANO, the emission layer EL and the cathode electrode CAT stacked sequentially. In particular, the cathode electrode CAT may include the first cathode layer CAT1 and the second cathode layer CAT2 sequentially stacked.

The first cathode layer CAT1 may include metal oxide material. For example, the first cathode layer CAT1 may include a metal oxide material selected at least one of aluminum oxide (Al₂O₃), molybdenum oxide (MoO), magnesium oxide (MgO), calcium oxide (CaO) and arium oxide (BaO). The first cathode layer CAT1 may have a thickness of 10 Å to 200 Å.

The second cathode layer CAT2 may include metal material. For example, the second cathode layer CAT2 may include any one metal of aluminum (Al), silver (Ag), molybdenum (Mo), gold (Au), magnesium (Mg), calcium (Ca) and barium (Ba). The second cathode layer CAT2 may have a thickness of 100 Å to 3,000 Å. In one embodiment, the second cathode layer CAT2 has a thickness of 500 Å to 2,000 Å. In particular, the second cathode layer CAT2 is made of metal material thicker than the first cathode layer CAT1 made of metal oxide material.

In the first embodiment, the second cathode layer CAT2 may be deposited at the topmost layer, so there may be no other additional layer such as an encapsulation layer for sealing the light emitting diode there-after. However, functional elements for other purposes may be further deposited. For example, an additional element bonded using an adhesive layer other than the continuous deposition or continuously applied functional layer may be further disposed.

The second cathode layer CAT2 is formed on the uppermost portion, and is formed to completely cover the first cathode layer CAT1. As described with FIGS. 5 and 6, the first cathode layer CAT1 may deposited as covering entire display area AA and may be extended to the non-display area NDA. In addition, the first cathode layer CAT1 may be deposited as completely covering entire emission layer EL. That is, the first cathode layer CAT1 may cover the end edges of the emission layer EL, and may contact the layer disposed under the emission layer EL.

The second cathode layer CAT2 may completely cover the display area AA, further extended to the non-display area NDA. In particular, the second cathode layer CAT2 may have larger area than the first cathode layer CAT1 to completely cover the first cathode layer CAT1 and the emission layer EL. That is, the second cathode layer CAT2 may cover the edge of the first cathode layer CAT1, and be in surface contact with the layers exposed out of the edge of the first cathode layer CAT1.

### Second Embodiment

Hereinafter, referring to FIG. 8, a structure of an electroluminescence display of the second embodiment of the present disclosure will be explained. In convenience, the description may be focused on the light emitting diode OLE. FIG. 8 is a cross-sectional view, enlarging the rectangular area X in FIG. 4, for illustrating a stack structure of a light emitting diode of the electroluminescence display according to a second embodiment of the present disclosure.

Referring to FIG. 8, a light emitting diode of the electroluminescence display according the second embodiment of the present disclosure includes an anode electrode ANO, an emission layer EL and a cathode electrode CAT. In particular, the cathode electrode CAT includes a first cathode layer CAT1 and a second cathode layer CAT2 sequentially stacked.

The first cathode layer CAT1 may include a metal oxide layer 10 and a metal layer 20 stacked sequentially. For example, the metal oxide layer 10 may include a metal oxide material selected at least one of aluminum oxide (Al₂O₃), molybdenum oxide (MoO), magnesium oxide (MgO), calcium oxide (CaO) and arium oxide (BaO). The metal layer 20 may include any one metal of aluminum (Al), silver (Ag), molybdenum (Mo), gold (Au), magnesium (Mg), calcium (Ca) and barium (Ba).

For example, the first cathode layer CAT1 may include a double stacked layer having a metal oxide layer 10 made of aluminum oxide and a metal layer 20 made of aluminum stacked sequentially. The metal oxide layer 10 made of aluminum oxide may have a thickness of 10 Å to 200 Å. The metal layer 20 made of aluminum may have a thickness of 100 Å to 3,000 Å. As described above, since the aluminum oxide may have relatively thin thickness of 10 Å to 200 Å, it may be in a state in which it can easily overcome the work function barrier that prevents or at least reduces electron movement, so it may be used as a conductive layer. In particular, the metal layer 20 made of metal material may be thicker than the metal oxide layer 10 made of metal oxide material.

The second cathode layer CAT2 may have the same stacked structure with the first cathode layer CAT1. That is, the second cathode layer CAT2 may include a metal oxide layer 10 and a metal layer 20 sequentially stacked.

In another example, even though not shown in figures, the first cathode layer CAT1 may be stacked by changing the stacking order of the metal oxide layer 10 and the metal layer 20.

In the second embodiment, the stacking order of the metal oxide layer 10 and the metal layer 20 for the first cathode layer CAT1 and the second cathode layer CAT2 may be variously changed. However, in any case, the first cathode layer CAT1 has a larger area size than the emission layer EL to completely cover entire of the emission layer EL. In addition, the second cathode layer CAT2 disposed at the topmost layer may have larger area than the first cathode layer CAT1 to completely cover the first cathode layer CAT1.

### Third Embodiment

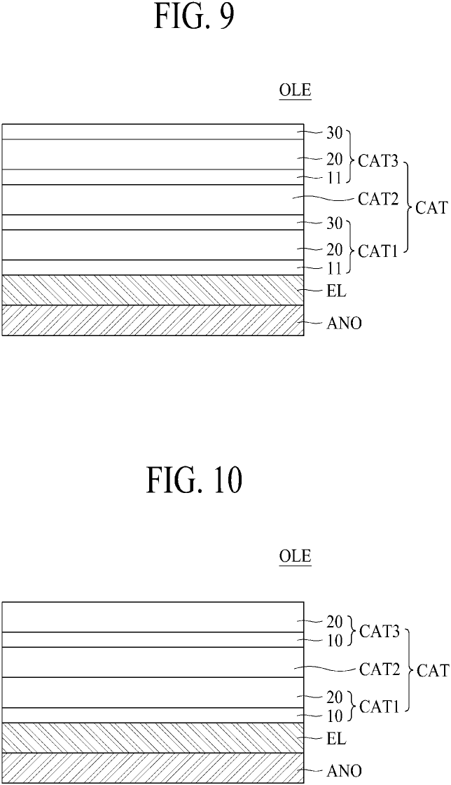

Referring to FIG. 9, a structure of an electroluminescence display according to the third embodiment of the present disclosure will be explained. FIG. 9 is a cross-sectional view, enlarging the rectangular area X in FIG. 4, for illustrating a stack structure of a light emitting diode of the electroluminescence display according to a third embodiment of the present disclosure.

Referring to FIG. 9, a light emitting diode of the electroluminescence display according the third embodiment of the present disclosure includes an anode electrode ANO, an emission layer EL and a cathode electrode CAT. In particular, the cathode electrode CAT includes a first cathode layer CAT1, a second cathode layer CAT2 and a third cathode layer CAT3 sequentially stacked.

The first cathode layer CAT1 may include a lower metal oxide layer 11, a metal layer 20 and an upper metal oxide layer 30 stacked sequentially. For example, the lower metal oxide layer 11 may include a metal oxide material selected at least one of aluminum oxide (Al₂O₃), molybdenum oxide (MoO), magnesium oxide (MgO), calcium oxide (CaO) and arium oxide (BaO). The metal layer 20 may include any one metal of aluminum (Al), silver (Ag), molybdenum (Mo), gold (Au), magnesium (Mg), calcium (Ca) and barium (Ba). The upper metal oxide layer 30 may include the same material as the lower metal oxide layer 11.

For example, the first cathode layer CAT1 may include a triple stacked layer having a lower metal oxide layer 11 made of aluminum oxide, a metal layer 20 made of aluminum and an upper metal oxide layer 30 made of aluminum oxide stacked sequentially. The lower metal oxide layer 11 and the upper metal oxide layer 30 made of aluminum oxide may have a thickness of 10 Å to 200 Å, respectively. The metal layer 20 made of aluminum may have a thickness of 500 Å to 5,000 Å. In particular, it is preferable that the metal layer 20 made of aluminum may be thicker than the lower metal oxide layer 11 and the upper metal oxide layer 30 made of aluminum oxide.

The second cathode layer CAT2 may include conductive resin materials. The conductive resin materials may include a domain material made of a resin material with high electron mobility and a dopant for lowering the barrier energy of the domain material. The resin materials, the domain material, having high electron mobility may include any one selected from Alq3, TmPyPB, Bphen, TAZ and TPB.

The dopant materials may include an alkali-based doping material. For example, the dopant materials may include at least any one of lithium (Li), cesium (Cs), cesium oxide (Cs₂O₃), cesium nitride (CsN₃), rubidium (Rb) and rubidium oxide (Rb₂O). In another example, the dopant materials may include fullerene (C60) in which 60 carbon atoms having high electron mobility are bonded in the shape of a soccer ball.

The third cathode layer CAT3 may have the same stacking structure same with the first cathode layer CAT1. For example, the third cathode layer CAT3 may include a triple stacked layer having a lower metal oxide layer 11 made of aluminum oxide, a metal layer 20 made of aluminum and an upper metal oxide layer 30 made of aluminum oxide stacked sequentially. The lower metal oxide layer 11 and the upper metal oxide layer 30 made of aluminum oxide may have a thickness of 10 Å to 200 Å, respectively. The metal layer 20 made of aluminum may have a thickness of 100 Å to 3,000 Å. In particular, the metal layer 20 is made of aluminum may be thicker than the lower metal oxide layer 11 and the upper metal oxide layer 30 made of aluminum oxide.

For example, the metal layer 20 may have a thickness of 500 Å, and the lower and upper metal oxide layers 11 and 30 may have a thickness of 50 Å. In addition, the second cathode layer CAT2 may include a conductive resin material, and have a thickness of 2 µm (micrometer) to 4 µm (micrometer). The second cathode layer CAT2 is interposed between the first cathode layer CAT1 and the third cathode layer CAT3 made of inorganic materials to relieve stress between the inorganic thin layers, so that it is suitable to prevent the cathode electrode CAT from being damaged.

Even though it is not shown in figures, the first cathode layer CAT1 may have a structure in which a lower metal layer, a metal oxide layer and an upper metal layer are sequentially stacked. Further, the third cathode layer CAT3 may also have a structure in which a lower metal layer, a metal oxide layer and an upper metal layer are sequentially stacked. That is, the first cathode layer CAT1 and the third cathode layer CAT3 may have the same structure, or different structure from each other.

### Fourth Embodiment

Hereinafter, referring to FIG. 10, a structure of an electroluminescence display according to the fourth embodiment of the present disclosure will be explained. FIG. 10 is a cross-sectional view, enlarging the rectangular area X in FIG. 4, for illustrating a stack structure of a light emitting diode of the electroluminescence display according to a fourth embodiment of the present disclosure.

Referring to FIG. 10, a light emitting diode of the electroluminescence display according the fourth embodiment of the present disclosure includes an anode electrode ANO, an emission layer EL and a cathode electrode CAT. In particular, the cathode electrode CAT includes a first cathode layer CAT1, a second cathode layer CAT2 and a third cathode layer CAT3 sequentially stacked.

The first cathode layer CAT1 may include a metal oxide layer 10 and a metal layer 20 stacked sequentially. For example, the metal oxide layer 10 may include a metal oxide material selected at least one of aluminum oxide (Al₂O₃), molybdenum oxide (MoO), magnesium oxide (MgO), calcium oxide (CaO) and arium oxide (BaO). The metal layer 20 may include any one metal of aluminum (Al), silver (Ag), molybdenum (Mo), gold (Au), magnesium (Mg), calcium (Ca) and barium (Ba).

For example, the first cathode layer CAT1 may include a double stacked layer having a metal oxide layer 10 made of aluminum oxide and a metal layer 20 made of aluminum stacked sequentially. The metal oxide layer 10 made of aluminum oxide may have a thickness of 10 Å to 200 Å. The metal layer 20 made of aluminum may have a thickness of 100 Å to 3,000 Å. In particular, the metal layer 20 made of metal material may be thicker than the metal oxide layer 10 made of metal oxide material.

The second cathode layer CAT2 may include conductive resin materials. The conductive resin materials may include a domain material made of a resin material with high electron mobility and a dopant for lowering the barrier energy of the domain material. The resin materials, the domain material, having high electron mobility may include any one selected from Alq3, TmPyPB, Bphen, TAZ and TPB.

The dopant materials may include an alkali-based doping material. For example, the dopant materials may include at least any one of lithium (Li), cesium (Cs), cesium oxide (Cs₂O₃), cesium nitride (CsN₃), rubidium (Rb) and rubidium oxide (Rb₂O). In another example, the dopant materials may include fullerene (C60) in which 60 carbon atoms are bonded in the shape of a soccer ball.

The third cathode layer CAT3 has a same stacked structure as the first cathode layer CAT1 in one embodiment. Alternatively, the third cathode layer CAT3 may have a reversely stacked structure with the first cathode layer CAT1. For example, the third cathode layer CAT3 may have a structure in which a metal layer 20 made of aluminum and a metal oxide layer 10 made of aluminum oxide are sequentially stacked. The metal oxide layer 10 made of a metal oxide material has a thickness of 10 Å to 200 Å. The metal layer 20 may have a thickness of 100 Å to 3,000 Å. In particular, the metal layer 20 made of aluminum may be thicker than the metal oxide layer 10 made of aluminum oxide.

The second cathode layer CAT2 may include a conductive resin material, and have a thickness of 2 µm (micrometer) to 4 µm (micrometer). The second cathode layer CAT2 is interposed between the first cathode layer CAT1 and the third cathode layer CAT3 made of inorganic materials to relieve stress between the inorganic thin layers, so that it is suitable to prevent the cathode electrode CAT from being damaged.

Even though it is not shown in figures, the first cathode layer CAT1 may have a structure in which a metal layer 20 and a metal oxide layer 10 are sequentially stacked. Further, the third cathode layer CAT3 may also have a structure in which a metal oxide layer 10 and a metal layer 20 are sequentially stacked. That is, the first cathode layer CAT1 and the third cathode layer CAT3 may have the same structure, or different structure from each other.

### Fifth Embodiment

Hereinafter, referring to FIG. 11, a structure of an electroluminescence display according to the fifth embodiment of the present disclosure will be explained. FIG. 11 is a cross-sectional view, enlarging the rectangular area X in FIG. 4, for illustrating a stack structure of a light emitting diode of the electroluminescence display according to a fifth embodiment of the present disclosure.

Referring to FIG. 11, a light emitting diode of the electroluminescence display according the fifth embodiment of the present disclosure includes an anode electrode ANO, an emission layer EL and a cathode electrode CAT. In particular, the cathode electrode CAT includes a first cathode layer CAT1, a second cathode layer CAT2 and a third cathode layer CAT3 sequentially stacked.

The first cathode layer CAT1 may include a metal oxide layer 10 and a metal layer 20 stacked sequentially. For example, the metal oxide layer 10 may include a metal oxide material selected at least one of aluminum oxide (Al₂O₃), molybdenum oxide (MoO), magnesium oxide (MgO), calcium oxide (CaO) and arium oxide (BaO). The metal layer 20 may include any one metal of aluminum (Al), silver (Ag), molybdenum (Mo), gold (Au), magnesium (Mg), calcium (Ca) and barium (Ba).

For example, the first cathode layer CAT1 may include a double stacked layer having a metal oxide layer 10 made of aluminum oxide and a metal layer 20 made of aluminum stacked sequentially. The metal oxide layer 10 made of aluminum oxide may have a thickness of 10 Å to 200 Å. The metal layer 20 made of aluminum may have a thickness of 100 Å to 3,000 Å. In particular, the metal layer 20 made of metal material may be thicker than the metal oxide layer 10 made of metal oxide material.

The second cathode layer CAT2 may have the same stacked structure with the first cathode layer CAT1. For example, the second cathode layer CAT2 may include a metal oxide layer 10 and a metal layer 20 sequentially stacked. The metal oxide layer 10 made of aluminum oxide may have a thickness of 10 Å to 200 Å. The metal layer 20 made of aluminum may have a thickness of 100 Å to 3,000 Å. In particular, the metal layer 20 made of metal material may be thicker than the metal oxide layer 10 made of metal oxide material.

The third cathode layer CAT3 may have the same stacking structure same with the first cathode layer CAT1. For example, the first cathode layer CAT3 may include a metal oxide layer 10 and a metal layer 20 sequentially stacked.

Even though it is not shown in figures, the first cathode layer CAT1 may have different stacked structure from the second cathode layer CAT2. In addition, the third cathode layer CAT2 may have different stacked structure from the first cathode layer CAT1 or the second cathode layer CAT2.

### Sixth Embodiment

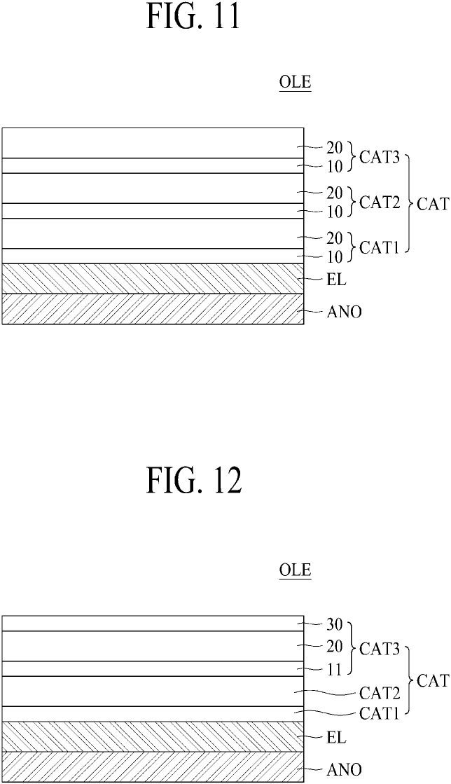

Hereinafter, referring to FIG. 12, a structure of an electroluminescence display according to the sixth embodiment of the present disclosure will be explained. FIG. 12 is a cross-sectional view, enlarging the rectangular area X in FIG. 4, for illustrating a stack structure of a light emitting diode of the electroluminescence display according to a sixth embodiment of the present disclosure.

Referring to FIG. 12, a light emitting diode of the electroluminescence display according the fourth embodiment of the present disclosure includes an anode electrode ANO, an emission layer EL and a cathode electrode CAT. In particular, the cathode electrode CAT includes a first cathode layer CAT1, a second cathode layer CAT2 and a third cathode layer CAT3 sequentially stacked.

The first cathode layer CAT1 may have single layer structure including a metal oxide layer only. For example, the first cathode layer CAT1 may include a metal oxide material selected at least one of aluminum oxide (Al₂O₃), molybdenum oxide (MoO), magnesium oxide (MgO), calcium oxide (CaO) and barium oxide (BaO).

For example, the first cathode layer CAT1 may have a single layered structure including an aluminum oxide layer only. The first cathode layer CAT1 made of the aluminum oxide material may have a thickness of 10 Å to 200 Å.

The second cathode layer CAT2 may include conductive resin materials. The conductive resin materials may include a domain material made of a resin material with high electron mobility and a dopant for lowering the barrier energy of the domain material. The resin materials, the domain material, having high electron mobility may include any one selected from Alq3, TmPyPB, Bphen, TAZ and TPB.

The dopant materials may include an alkali-based doping material. For example, the dopant materials may include at least any one of lithium (Li), cesium (Cs), cesium oxide (Cs₂O₃), cesium nitride (CsN₃), rubidium (Rb) and rubidium oxide (Rb₂O). In another example, the dopant materials may include fullerene (C60) in which 60 carbon atoms are bonded in the shape of a soccer ball.

The third cathode layer CAT3 may include a triple stacked layer having a lower metal oxide layer 11 made of aluminum oxide, a metal layer 20 made of aluminum and an upper metal oxide layer 30 made of aluminum oxide stacked sequentially. The lower metal oxide layer 11 and the upper metal oxide layer 30 made of aluminum oxide may have a thickness of 10 Å to 200 Å, respectively. The metal layer 20 made of aluminum may have a thickness of 100 Å to 3,000 Å. In particular, the metal layer 20 made of aluminum may be thicker than the lower metal oxide layer 11 and the upper metal oxide layer 30 made of aluminum oxide.

The second cathode layer CAT2 may include a conductive resin material, and have a thickness of 2 µm(micrometer) to 4 µm(micrometer). The second cathode layer CAT2 is interposed between the first cathode layer CAT1 and the third cathode layer CAT3 made of inorganic materials to relieve stress between the inorganic thin layers, so that it is suitable to prevent the cathode electrode CAT from being damaged.

Even though it is not shown in figures, the first cathode layer CAT1 may have a structure in which a lower metal layer, a metal oxide layer and an upper metal layer are sequentially stacked. In this case, the lower metal layer and the upper metal layer may have a thickness of 100 Å to 3,000 Å, respectively. The metal oxide layer may have a thickness of 10 Å to 200 Å. In particular, the upper metal layer and the lower metal layer made of metal material may have thicker thickness than the oxide metal layer made of oxide metal material.

The electroluminescence displays according to the present disclosure described above include a light emitting diode in which an anode electrode ANO, an emission layer EL and a cathode electrode CAT are sequentially stacked. In particular, the cathode electrode CAT may have not only a function of a common electrode to which a common voltage is applied, but also an encapsulating function for preventing or at least reducing oxygen or foreign materials from penetrating into the emission layer EL from the outside. To these purposes, the cathode electrode CAT may have a structure in which a plurality of conductive layers are sequentially stacked. The cathode electrode CAT may include a metal layer having excellent conductivity. The metal layer is formed to a thickness of 100 Å to 3,000 Å, preferably 500 Å or more, in order to keep the sheet electric resistance of the cathode electrode CAT in low state as possible. Since the metal oxide layer may also function as a conductive layer, it is preferable to have a thin thickness of 10 Å to 200 Å. In addition, the cathode electrode CAT may include a resin material having a relatively thick thickness of 2 µm to 4 µm, and excellent elasticity in order to prevent the cathode electrode from being damaged by an external force. In particular, since the resin material may function as a conductive layer, it is made of a domain resin material having high electron mobility and a conductive resin material including an alkali-based metal dopant for improving the electron mobility.

The embodiments described until now have been explained as basic structures in various stacked structure of conductive layers configuring the cathode electrode. However, it is not limited thereto. Two or more embodiments may be combined to form a multi-layered cathode electrode. For example, the cathode electrode may be configured to have a complex stacked structure by combining the stacked structure according to any one of the second to sixth embodiments to the stacked structure according to the first embodiment.

### Seventh Embodiment

In the above explained embodiments, the cases in which the cathode electrode may have a multi-layer structure for performing an encapsulating function have been described.

FIG. 13 is a cross-sectional view for illustrating a stack structure of a light emitting diode of the electroluminescence display according to a seventh embodiment of the present disclosure. Referring to FIG. 13, an electroluminescence display according to the seventh embodiment may have a structure in which an anode electrode ANO, an emission layer EL and a cathode electrode CAT are sequentially stacked.

In particular, the cathode electrode CAT includes three cathode layers sequentially stacked. For example, the cathode electrode CAT may include a first cathode layer CAT1, a second cathode layer CAT2 and a third cathode layer CAT3 sequentially stacked.

The first cathode layer CAT1 may formed of a metal material having a low sheet electric resistance, such as aluminum (Al), silver (Ag), molybdenum (Mo) or gold (Au). For example, the first cathode layer CAT1 may be a thin layer made of aluminum having a thickness of 100 Å to 200 Å

The second cathode layer CAT2 may be formed of a conductive resin material. The second cathode layer CAT2 may be made of the same material as the electron transport layer or the electron injection layer included in the emission layer EL. The second cathode layer CAT2 is preferably a conductive resin material having a dopant with a doping concentration of 3% to 30%. For example, the second cathode layer CAT2 may be made of a conductive resin material having a thickness of 500 Å to 900 Å.

In one embodiment, the third cathode layer CAT3 is formed of a metal material having a low sheet electric resistance in order to lower the overall sheet electric resistance of the cathode electrode CAT to a relatively thicker thickness than the first and second cathode layers CAT1 and CAT2. For example, the third cathode layer CAT3 may be formed of aluminum having a thickness of at least 2,000 Å.

The cathode electrode CAT having a thickness and a stacked structure as explained above may reduce reflectance of light incident from a lower direction (i.e., from the first cathode electrode layer CAT1). The description will be made with reference to arrows indicating the optical path shown in FIG. 13.

An incident light ① entering from the lower outside of the cathode electrode CAT may pass through the transparent anode electrode ANO and the emission layer EL, and be partially reflected from the lower surface of the first cathode layer CAT1 to be a first reflected light ② going to the direction where the substrate SUB is disposed. Since the first cathode electrode layer CAT1 may have a thin thickness of 200 Å or less, all of the incident light ① are not reflected. For example, about 40% of the incident light ① may be reflected as a first reflected light (2), and the remained 60% of the incident light ① may pass through the first cathode layer CAT1. A transmitted light ③ passing through the first cathode layer CAT1 may pass through the transparent second cathode layer CAT2. After that, the transmitted light ③ may be reflected by the third cathode layer CAT3. Since the third cathode layer CAT3 has a thickness of 2,000 Å or more, all of the transmitted light ③ may be reflected, and proceed toward the substrate SUB as a second reflected light ④.

Here, by adjusting the thickness of the second cathode layer CAT2, the phases of the first reflected light ② and the second reflected light ④ may be controlled to cancel each other. As a result, the luminance of the reflected light, which is the intensity of the reflected light incident and reflected from the lower surface of the cathode electrode CAT, may be reduced to a level of 2%.

Meanwhile, among the lights emitted from the emission layer EL, the amount of light emitted to the cathode electrode CAT and reflected to the direction of the substrate SUB, by the same optical path, may be reduced by 2%. However, since the light emitted from the emission layer EL is emitted in all directions, the amount of light reduced by the cathode electrode CAT is only about 50% of the total amount of light, and the remained 50% is emitted to the direction of the substate SUB.

The electroluminescence display according to the seventh embodiment may be a bottom emission type in which a cathode electrode including a triple-layer stack structure. In addition, the reflectance of the external light may be suppressed in maximum by the structure of the cathode electrode having the triple-layer stacked structure. Therefore, there is no need to dispose a polarizing element to reduce external light reflection outside the substrate SUB. The polarizing element has a positive effect of suppressing the external light reflection, but has a negative effect of reducing the amount of light emitted from the emission layer EL by at least 50%.

In the electroluminescence display according to the seventh embodiment, the amount of light emitted from the emission layer EL is reduced by about 50% by the cathode electrode having a triple-layered stack structure, but this is almost the same as the reduction in the amount of light by the polarizing element. Accordingly, the electroluminescence display according to the present disclosure may minimize the external light reflection while providing the luminous efficiency of the emission layer EL having the same level as the display including the polarizing element without using an expensive polarizing element.

In addition, when it is required, the cathode electrode CAT according to the seventh embodiment may have the various structure as described in the second to sixth embodiments.

### Eighth Embodiment

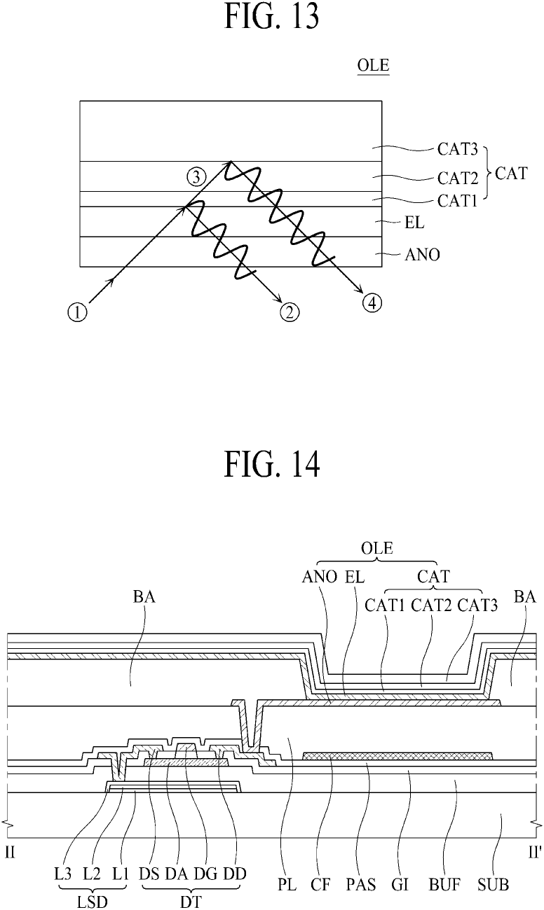

In the seventh embodiment, with a triple-layer stacked cathode electrode, the structure for suppressing external light reflection by the cathode electrode is provided. In the eighth embodiment with reference to FIG. 14, a structure for suppressing external light reflection by a metallic line such as gate lines or data lines as well as by the cathode electrode in the bottom emission type electroluminescence display will be described. FIG. 14 is a cross-sectional view for illustrating a stack structure of a light emitting diode of the electroluminescence display according to an eighth embodiment of the present disclosure.

FIG. 14 illustrates a bottom emission type electroluminescence display including a thin film transistor having a top gate structure according to the present disclosure. In FIG. 14, in convenience, the thin film transistor includes only the driving thin film transistor DT. However, it is not limited thereto. As shown in FIG. 4, the thin film transistor includes the switching thin film transistor ST.

A light shielding layer LSD is disposed on a substrate SUB. The light shielding layer LSD may be a light blocking element for protecting the driving semiconductor layer DA of the driving thin film transistor DT from external light. In addition, the light shielding layer LSD may be used for the data line DL or driving current line VDD. In this case, the light shielding layer LSD may be connected to the driving source electrode DS of the driving thin film transistor DT.

To prevent the influence of external light incident into the driving semiconductor layer DA from the outside of the substrate SUB, the light shielding layer LSD may be disposed as overlapping with the driving semiconductor layer DA. In addition, the light shielding layer LSD may be used as the driving current line VDD connected to the driving source electrode DS of the driving thin film transistor DT. To do so, it is preferable that the light shielding layer LSD may include a metal material such as copper (Cu).

In the case that the light shielding layer LSD include a metal material, external light incident from the outside of the substrate SUB may be reflected by the light shielding layer LSD, and thus the reflected light may cause deterioration of display quality. In order to prevent this phenomenon, a low reflection structure is applied to the light shielding layer LSD.

For example, the light shielding layer LSD may have a triple-layered structure. The light shielding layer LSD may include a first layer L1, a second layer L2 and a third layer L3 stacked sequentially. The first layer L1 may be made of tantalum (Ta) having a thickness of 100 Å to 200 Å. The second layer L2 may be made of molybdenum oxide (MoOx) having a thickness of 500 Å to 900 Å. The molybedenum oxide may have transparency property. The third layer L3 may be made of a metal material having a low sheet resistance such as copper (Cu) having a thickness of at least 2,000 Å. The third layer L3 may be formed of a double metal layer in which copper and molybdenum-titanium are stacked.

Even though it is not shown in figures, for another example, the light shielding layer LSD may have a double-layered structure. In this case, the light shielding layer LSD may include a first layer and a second layer sequentially stacked. The first layer disposed at lower layer may be made of metal oxide having a thickness of 500 Å to 900 Å. The second layer disposed at upper layer may be made of metal material having a low sheet resistance such as copper (Cu) having a thickness of at least 2,000 Å. In detail, the first layer may be made of a transparent oxide material such as molybdenum-titanium oxide (Moti Ox), molybedeum oxide tantalum (MoOx:Ta), tungsten oxide (WOx) and molybdenum-copper oxide (MoCuOx). In addition, the second layer may be made of a single metal layer including copper, or a double metal layer in which copper and molybdenum-titanium (MoTi) are stacked.

A buffer layer BUF is deposited on the light shielding layer LSD. The thin film transistor is formed on the buffer layer BUF. The thin film transistor may include a switching thin film transistor (not shown) and a driving thin film transistor DT. The passivation layer PAS is deposited on the substrate SUB having the thin film transistor. A color filter CT is formed on the passivation layer PAS. It is preferable that the color filter CF may be disposed to completely overlap the light emitting diode OLE to be formed later. In some cases, the color filter CF may have larger areal size than the light emitting diode OLE. A planarization layer PL is deposited on the color filter CF. The light emitting diode OLE is formed on the planarization layer PL.

The light shielding layer LSD according to the eighth embodiment may have the same structure as the cathode electrode CAT in the seventh embodiment. The light shielding layer LSD may have a thin metal layer, a transparent conductive layer and a thick metal layer sequentially stacked. Therefore, the light shielding layer LSD may minimize the reflectance of light incident from the outside to a level of 2% in the same manner as the light path described in the seventh embodiment.

Further, even though it is not shown in figures, the gate line GL may have the low reflection structure as the light shielding layer LSD. The driving gate electrode DG and the switching gate electrode SG may be covered by the light shielding layer LSD. However, as the gate line GL crosses to light shielding layer LSD used for the data line DL and the driving current line VDD, the most portions of the gate line GL may not be covered by the light shielding layer LSD but be exposed. Therefore, display quality may be deteriorated by the external light reflection from the gate line GL. To prevent this phenomenon, the gate line GL may also have a triple-layer structure such as the light shielding layer LSD.

For example, the gate line GL may include a first layer L1, a second layer L2 and a third layer L3 sequentially stacked. The first layer L1 may be made of tantalum (Ta) having a thickness of 100 Å to 200 Å. The second layer L2 may be made of molybdenum oxide (MoOx) having a thickness of 500 Å to 900 Å. The molybedenum oxide may have transparency property. The third layer L3 may be made of a metal material having a low sheet resistance such as copper (Cu) having a thickness of at least 2,000 Å. The third layer L3 may be formed of a double metal layer in which copper and molybdenum-titanium are stacked.

Even though it is not shown in figures, for another example, the gate line may have a double-layered structure. In this case, the gate line may include a first layer and a second layer sequentially stacked. The first layer disposed at lower layer may be made of metal oxide having a thickness of 500 Å to 900 Å. The second layer disposed at upper layer may be made of metal material having a low sheet resistance such as copper (Cu) having a thickness of at least 2,000 Å. In detail, the first layer may be made of a transparent oxide material such as molybdenum-titanium oxide (MoTiOx), molybedeum oxide tantalum (MoOx:Ta), tungsten oxide (WOx) and molybdenum-copper oxide (MoCuOx). In addition, the second layer may be made of a single metal layer including copper, or a double metal layer in which copper and molybdenum-titanium (MoTi) are stacked.

By such a structure, it is possible to reduce the luminance of reflection to 5% or less. In this case, as the bank BA is a white organic material, it is hard to further lower the luminance of reflection. However, by forming the bank BA of a black organic material, the luminance of the reflection may be lowered to a level of 2%.

### Ninth Embodiment

In the seventh and eighth embodiments, with a triple-layer stacked structure on the cathode electrode and lines, an effect of suppressing external light reflection may be further provided. In the ninth embodiment with reference to FIG. 15, a structure for suppressing external light reflection in a region excluding the cathode electrode and lines in the bottom emission type electroluminescence display will be explained. FIG. 15 is a cross-sectional view for illustrating a stack structure of a light emitting diode of the electroluminescence display according to a nineth embodiment of the present disclosure.

According to the seventh and eighth embodiments, although external light reflection is suppressed in the cathode electrode CAT and lines, there is still a possibility of external light reflection in portions excluding these regions. In particular, considering the bank BA region, as the cathode electrode CAT having a triple layer structure is disposed, the external light reflection by the cathode electrode CAT may be lowered to the level of 2%. However, even a level of 2% may significantly adversely affect to the display quality.

The ninth embodiment further proposes an additional structure for maximally suppressing external light reflection. For example, the bank BA may be made of a black organic material. In one embodiment, the black organic material includes an organic material excellent in light absorption property. As a result, in the portions where the light emitting diode OLE is formed, the external light reflection may be lowered to a level of 2%. In the other portions covered by the bank BA, 2% or more external light reflection may be further absorbed by the bank BA made of black organic material, so that the external light reflection may be further lowered to a level of less than 1%.

In addition, for the bottom emission type, the color filter CF may be disposed under the planarization layer PL. In FIG. 14, the color filter CF may be disposed as fully overlapping the emission area formed at the light emitting diode OLE. Meanwhile, in the ninth embodiment, the color filter CF may be disposed as covering other areas than the emission area.

For example, in the red pixel, the red color filter may be disposed at the emission area. In addition, in the red pixel, the red color filter may be extended to out of the emission area. In the blue pixel, the blue color filter may be disposed at the emission area, and the blue color filter may be extended to other areas from the emission area. In the green pixel, the green color filter may be disposed at the emission area, and the green color filter may be extended to other areas from the emission area.

When the color filter CF is extended to the entire pixel area, the bank BA may be a white bank made of white organic material or a black bank made of black organic material. When a black bank is used, external light reflection may be suppressed more.

In addition, the color filter CF may be disposed in various manners. For example, as explained above, a plurality of pixels is arrayed on the substrate SUB. Each pixel may include three sub-pixels at least. For example, one pixel may include a red sub-pixel, a green sub-pixel and a blue sub-pixel. The red sub-pixel has a red color filter, the green sub-pixel has a green color filter, and the blue sub-pixel has a blue color filter.

Each sub-pixel may include an emission area occupied by the light emitting diode, and a non-emission area where lines and thin film transistor are disposed. For the top emission type, the emission area may have substantially similar size as the size of the sub-pixel. However, for the bottom emission type, the emission area may have the same size of the light emitting diode.

Therefore, in the bottom emission type, the color filters may be disposed as overlapping the light emitting diode which defines the emission area. However, in the ninth embodiment, the color filter may be disposed as covering entire size of the sub-pixel including the emission area and the non-emission area. For example, in the red sub-pixel, the red color filter may be disposed as covering entire areal size of the red sub-pixel including the emission area and the non-emission area. In the green sub-pixel, the green color filter may be disposed as covering entire areal size of the green sub-pixel including the emission area and the non-emission area. In the blue sub-pixel, the blue color filter may be disposed as covering entire areal size of the blue sub-pixel including the emission area and the non-emission area.

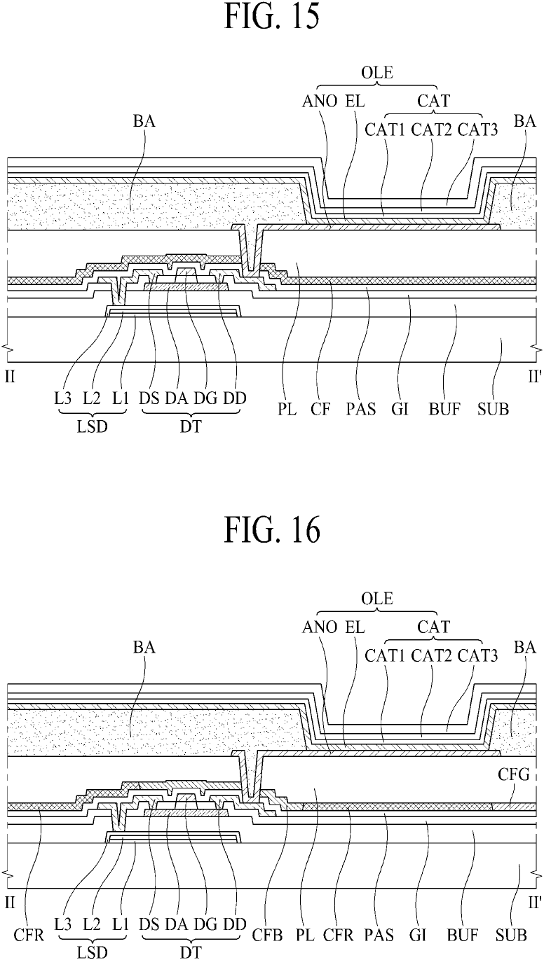

For another example, as shown in FIG. 16, the corresponding color filter may be disposed at the emission area, and the red, green and blue color filters may be disposed together in the non-emission area. FIG. 16 is a cross-sectional view for illustrating a stack structure of a light emitting diode of the electroluminescence display according to another example of the nineth embodiment of the present disclosure.

For example, the red color filter CFR may be disposed at the emission area of the red sub-pixel, and the red color filter CFR, the green color filter CFG and the blue color filter CFB may be disposed adjacent to each other on the same layer in the non-emission area. With the same manner, the green color filter CFG may be disposed at the emission area of the green sub-pixel, and, in the non-emission area, the red color filter CFR, the green color filter CFG and the blue color filter CFB may be disposed adjacent to each other on the same layer. Further, the blue color filter CFB may be disposed at the emission area of the blue sub-pixel, and the red color filter CFR, the green color filter CFG and the blue color filter CFB may be disposed adjacent to each other on the same layer in the non-emission area.

Here, the red, green and blue color filters disposed in the non-emission area may be arrayed with a same area ratio as each other. Otherwise, the area ratio of the blue color filter having a relatively low external light reflectance may be formed to be larger. For another example, as considering the reflection ratio (or reflectance) and the luminous reflectance (or visual sensation of reflectance), the area ratio of the green or red color filter may be formed to be larger depending on what kind of luminous reflectance is implemented.

Summarizing the features of the electroluminescence display according to the present disclosure described above, as the cathode electrode may have a multi-layer structure including a conductive resin material, it may have a simple structure without an additional encapsulation element. The embodiments described so far have been explained focusing on the most representative cases. In particular, for the most important feature of the present disclosure, since the cathode electrode includes an encapsulating function, an electroluminescence display may be implemented without an additional encapsulation layer. As a basic structure, the present disclosure has the characteristics in which the cathode electrode has at least a triple layer structure, as shown in FIG. 4.

In the triple layer structure provided for the cathode electrode according to the present disclosure, the first layer includes a metal layer or a metal oxide layer having high conductivity, the second layer includes a resin layer having conductivity, and the third layer includes a low-resistance metal layer for lowering the electric resistance of the cathode electrode. Here, the configuration of the first layer and the third layer may be varied, or an additional electrode layer may be further included to the basic triple-layer structure. Hereinafter, referring to figures, specific application examples that may be further implemented in the present disclosure will be described.

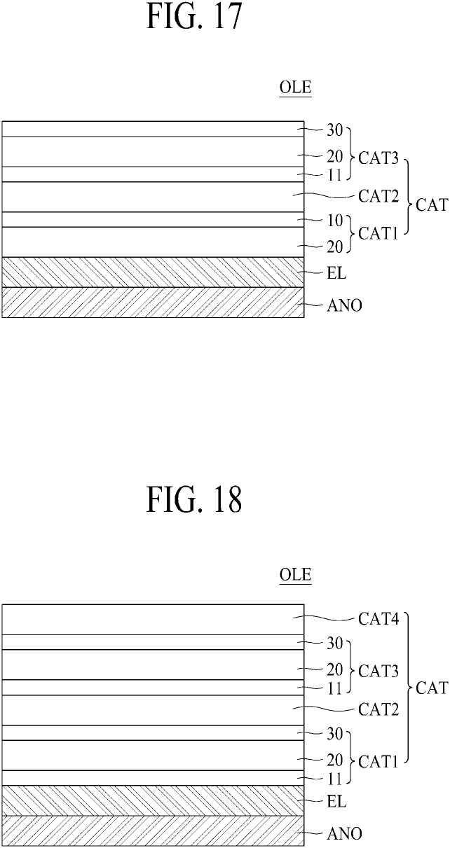

FIG. 17 is a cross-sectional view for illustrating a stack structure of a light emitting diode of the electroluminescence display according to a first application example of the present disclosure. Referring to FIG. 17, an electroluminescence display according to the first application example may have an anode electrode ANO, an emission layer EL and a cathode electrode CAT sequentially stacked. In particular, the cathode electrode CAT may include a first cathode layer CAT1, a second cathode layer CAT2 and a third cathode layer CAT3 stacked sequentially.

The first cathode layer CAT1 may include a metal layer 20 and a metal oxide layer 10 sequentially stacked. For example, the metal layer 20 may be at least one selected metal material from aluminum (Al), silver (Ag), molybdenum (Mo), gold (Au), magnesium (Mg), calcium (Ca) and barium (Ba). The metal oxide layer 10 may be at least one selected metal oxide material from aluminum oxide (Al₂O₃), molybdenum oxide (MoO), magnesium oxide (MgO), calcium oxide (CaO) and barium oxide (BaO).

The second cathode layer CAT2 may include a conductive resin material. The conductive resin material may include a domain material made of a resin material with high electron mobility and a dopant for lowering the barrier energy of the domain material.

The third cathode layer CAT3 may include a lower metal oxide layer 11, a metal layer 20 and an upper metal oxide layer 30 sequentially stacked. The lower metal oxide layer 11 and the upper metal oxide layer 30 made of metal oxide materials may have a thickness of 10 Å to 200 Å, respectively. The metal layer 20 may have a thickness of 100 Å to 3,000 Å. In particular, it is preferable that the metal layer 20 made of metal material may have thicker thickness than the lower metal oxide layer 11 and the upper metal oxide layer 30.

FIG. 18 is a cross-sectional view for illustrating a stack structure of a light emitting diode of the electroluminescence display according to a second application example of the present disclosure. Referring to FIG. 18, an electroluminescence display according to the second application example of the present disclosure may include an anode electrode ANO, an emission layer EL and a cathode electrode CAT sequentially stacked. In particular, the cathode electrode CAT may include a first cathode layer CAT1, a second cathode layer CAT2, a third cathode layer CAT3 and a fourth cathode layer CAT4 sequentially stacked.

The first cathode layer CAT1 may include a lower metal oxide layer 11, a metal layer 20 and an upper metal oxide layer 30 sequentially stacked. The lower metal oxide layer 11 and the upper metal oxide layer 30 made of metal oxide materials may have a thickness of 10 Å to 200 Å, respectively. The metal layer 20 may have a thickness of 100 Å to 3,000 Å. In particular, it is preferable that the metal layer 20 made of metal material may have thicker thickness than the lower metal oxide layer 11 and the upper metal oxide layer 30. For example, the lower metal oxide layer 11 may be at least one selected metal oxide material from aluminum oxide (Al₂O₃), molybdenum oxide (MoO), magnesium oxide (MgO), calcium oxide (CaO) and barium oxide (BaO). The metal layer 20 may be at least one selected metal material from aluminum (Al), silver (Ag), molybdenum (Mo), gold (Au), magnesium (Mg), calcium (Ca) and barium (Ba). The upper metal oxide layer 30 may include the same material as the lower metal oxide layer 11.

The second cathode layer CAT2 may include a conductive resin material. The conductive resin material may include a domain material made of a resin material with high electron mobility and a dopant for lowering the barrier energy of the domain material.

The third cathode layer CAT3 may include a lower metal oxide layer 11, a metal layer 20 and an upper metal oxide layer 30 sequentially stacked. The lower metal oxide layer 11 and the upper metal oxide layer 30 made of metal oxide materials may have a thickness of 10 Å to 200 Å, respectively. The metal layer 20 may have a thickness of 100 Å to 3,000 Å. In particular, it is preferable that the metal layer 20 made of metal material may have thicker thickness than the lower metal oxide layer 11 and the upper metal oxide layer 30.

The fourth cathode layer CAT4 may include a conductive resin material. The fourth cathode layer CAT4 may include the same material as the second cathode layer CAT2.

FIG. 19 is a cross-sectional view for illustrating a stack structure of a light emitting diode of the electroluminescence display according to a third application example of the present disclosure. Referring to FIG. 19, an electroluminescence display according to the third application example of the present disclosure may include an anode electrode ANO, an emission layer EL and a cathode electrode CAT sequentially stacked. In particular, the cathode electrode CAT may include a first cathode layer CAT1, a second cathode layer CAT2, a third cathode layer CAT3, a fourth cathode layer CAT4 and a fifth cathode layer CAT5 sequentially stacked.

The cathode electrode CAT according to FIG. 19 may further includes the fifth cathode layer CAT5 to the cathode electrode CAT according to FIG. 18. The fifth cathode layer CAT5 may be a conductive layer including a metal material selected any one of aluminum (Al), silver (Ag), molybdenum (Mo), gold (Au), magnesium (Mg), calcium (Ca) and barium (Ba). The fifth cathode layer CAT5 may have a thickness of 100 Å to 3,000 Å.

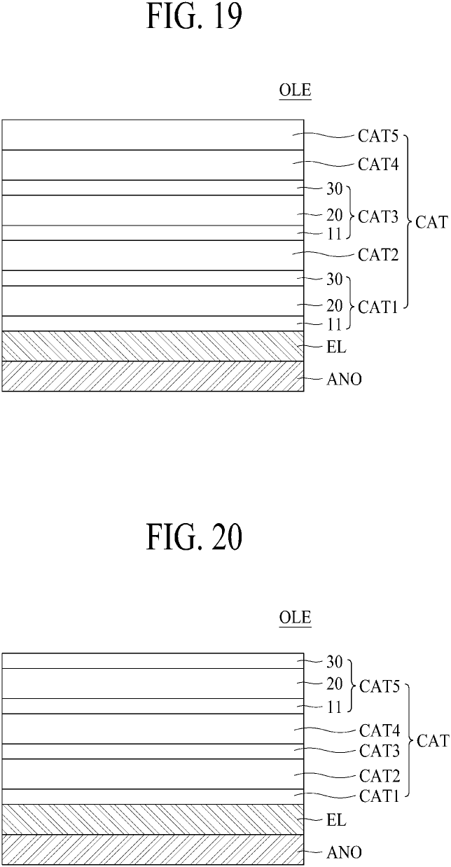

FIG. 20 is a cross-sectional view for illustrating a stack structure of a light emitting diode of the electroluminescence display according to a fourth application example of the present disclosure. Referring to FIG. 20, an electroluminescence display according to the fourth application example of the present disclosure may include an anode electrode ANO, an emission layer EL and a cathode electrode CAT sequentially stacked. In particular, the cathode electrode CAT may include a first cathode layer CAT1, a second cathode layer CAT2, a third cathode layer CAT3, a fourth cathode layer CAT4 and a fifth cathode layer CAT5 sequentially stacked.

The first cathode layer CAT1 may be a single layer including a metal oxide material. the first cathode layer CAT1 may include a metal oxide material selected at least one of aluminum oxide (Al₂O₃), molybdenum oxide (MoO), magnesium oxide (MgO), calcium oxide (CaO) and arium oxide (BaO). The first cathode layer CAT1 may have a thickness of 10 Å to 200 Å.

The second cathode layer CAT2 may be a single layer including a metal material. For example, the second cathode layer CAT2 may include any one metal of aluminum (Al), silver (Ag), molybdenum (Mo), gold (Au), magnesium (Mg), calcium (Ca) and barium (Ba). The second cathode layer CAT2 may have a thickness of 100 Å to 3,000 Å. In one embodiment, the second cathode layer CAT2 has a thickness of 500 Å to 2,000 Å. In particular, the second cathode layer CAT2 made of metal material is thicker than the first cathode layer CAT1 made of metal oxide material.

The third cathode layer CAT3 may include the same material and the same thickness as the first cathode layer CAT1. Further, the fourth cathode layer CAT4 may include the same material and the same thickness as the second cathode layer CAT2.

The fifth cathode layer CAT5 may include a lower metal oxide layer 11, a metal layer 20 and an upper metal oxide layer 30 sequentially stacked. The lower metal oxide layer 11 and the upper metal oxide layer 30 made of metal oxide materials may have a thickness of 10 Å to 200 Å, respectively. The metal layer 20 may have a thickness of 100 Å to 3,000 Å. In particular, it is preferable that the metal layer 20 made of metal material may have thicker thickness than the lower metal oxide layer 11 and the upper metal oxide layer 30.

In addition, the present disclosure provides an electroluminescence display in which the cathode electrode having triple-layer structure includes a first cathode layer having transparency, so that it may have an effect of suppressing reflection of external light due to destructive interference. Furthermore, as the various lines have a triple-layered structure including a transparent conductive layer, the reflection of external light may be further suppressed at the lines. Further, by applying black bank and/or color filter extending to non-display area, the reflection of external light may be still further suppressed.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. An electroluminescence display comprising:
a substrate;
an anode electrode on the substrate;
an emission layer on the anode electrode; and
a cathode electrode on the emission layer, the cathode electrode including a plurality of conductive layers that are sequentially stacked.

2. The electroluminescence display according to claim 1, wherein the plurality of conductive layers include:
a first metal oxide layer including a metal oxide material;
a first metal layer on the first metal oxide layer, the first metal layer including a metal material; and
a second metal oxide layer on the first metal layer, the second metal oxide layer including the metal oxide material.

3. The electroluminescence display according to claim 2, wherein the plurality of conductive layers further include a second metal layer having the metal material, the second metal layer on the second metal oxide layer.

4. The electroluminescence display according to claim 1, wherein the plurality of conductive layers include:
a first metal layer including a metal material;
a first metal oxide layer on the first metal layer, the first metal oxide layer including a metal oxide material; and
a second metal layer on the first metal oxide layer, the second metal layer including the metal material.

5. The electroluminescence display according to claim 4, wherein the plurality of conductive layers further include a second metal oxide layer including the metal oxide material, the second metal oxide layer on the second metal layer.

6. The electroluminescence display according to claim 1, wherein the plurality of conductive layers include:
a first metal layer having a metal material;
a first metal oxide layer on the first metal layer, the first metal oxide layer including a metal oxide material; and
a resin layer on the first metal oxide layer, the resin layer including a conductive resin material.

7. The electroluminescence display according to claim 6, wherein the plurality of conductive layers further include a second metal layer including the metal material, the second metal layer on the resin layer.

8. The electroluminescence display according to claim 7, wherein the plurality of conductive layers further include a second metal oxide layer including the metal oxide material, the second metal oxide layer on the second metal layer.

9. The electroluminescence display according to claim 1, wherein the plurality of conductive layers include:
a first metal oxide layer including a metal oxide material;
a first metal layer on the first metal oxide layer, the first metal layer including a metal material; and
a resin layer on the first metal layer, the resin layer including a conductive resin material.

10. The electroluminescence display according to claim 9, wherein the plurality of conductive layers further include a second metal oxide layer including the metal oxide material, the second metal oxide layer on the resin layer.

11. The electroluminescence display according to claim 10, wherein the plurality of conductive layers further include a second metal layer including the metal material, the second metal layer on the second metal oxide layer.

12. The electroluminescence display according to claim 2, wherein the metal material includes at least one of aluminum (Al), silver (Ag), molybdenum (Mo), gold (Au), magnesium (Mg), calcium (Ca) or barium (Ba), and
the metal oxide material includes at least one of aluminum oxide (Al₂O₃), molybdenum oxide (MoO), magnesium oxide (MgO), calcium oxide (CaO) and barium oxide (BaO).

13. The electroluminescence display according to claim 1, wherein the plurality of conductive layers include:
a first conductive layer in contact with the emission layer;
a second conductive layer in contact with the first conductive layer; and
a third conductive layer in contact with the second conductive layer.

14. The electroluminescence display according to claim 13, wherein each of the first conductive layer and the third conductive layer includes at least one of a metal layer or a metal oxide layer, and
wherein the metal layer is thicker than the metal oxide layer.

15. The electroluminescence display according to claim 14, wherein the metal oxide layer has a thickness in a range of 10 Å to 200 Å , and the metal layer has a thickness in a range of 100 Å to 3,000 Å .

16. The electroluminescence display according to claim 14, wherein the metal layer includes at least one of aluminum (Al), silver (Ag), molybdenum (Mo), gold (Au), magnesium (Mg), calcium (Ca) or barium (Ba), and
wherein the metal oxide layer includes at least one of aluminum oxide (Al₂O₃), molybdenum oxide (MoO), magnesium oxide (MgO), calcium oxide (CaO) and barium oxide (BaO).

17. The electroluminescence display according to claim 13, wherein the second conductive layer includes a conductive resin material.

18. The electroluminescence display according to claim 17, wherein the conductive resin material includes:
a domain material having at least one of Tris(8-hydroxyquinoline) aluminum, 1,3,5-tri(m-pyrid-3-yl-phenyl) benzene, Bathophenanthroline, 1,2,3-triazole and triphenyl bismuth; and
a dopant dispersed into the domain material, the dopant having an alkali metal material including at least one of lithium, cesium, cesium oxide, cesium nitride, rubidium or Buckminster-fullerene.

19. An electroluminescence display device comprising:
a substrate;
a transistor on the substrate;
a passivation layer on the transistor;
a planarization layer on the passivation layer, the planarization layer having a side surface;
a light emitting element on the planarization layer and electrically connected to the transistor, the light emitting element including an anode electrode, an emission layer on the anode electrode, and a multi-layer cathode electrode on the emission layer,
wherein the multi-layer cathode electrode extends past the emission layer such that at least a portion of the multi-layer cathode electrode overlaps the side surface of the planarization layer and is on the passivation layer.

20. The electroluminescence display device of claim 19, wherein the multi-layer cathode electrode comprises:
a first conductive layer in contact with the emission layer;
a second conductive layer in contact with the first conductive layer; and
a third conductive layer in contact with the second conductive layer.

21. The electroluminescence display device of claim 20, wherein each of the first conductive layer and the third conductive layer includes one of a metal layer or a metal oxide layer, and the second conductive layer includes conductive resin.
